(19) United States
(12) Patent Application Publication
(10) Pub. No.: US 2014/0166479 A1
(43) Pub. Date: Jun. 19, 2014

(54) SPUTTERING APPARATUS

(71) Applicant: Samsung Display Co., Ltd., Yongin-City (KR)

(72) Inventors: Il-Sang Lee, Yongin-City (KR); Sang-Wook Sin, Yongin-City (KR); Sun-Young Jung, Yongin-City (KR); Jin-Woo Park, Yongin-City (KR); Dong-Jin Kim, Yongin-City (KR)

(21) Appl. No.: 14/027,169

(22) Filed: Sep. 14, 2013

(30) Foreign Application Priority Data
Dec. 13, 2012 (KR) 10-2012-0145708

(51) Int. Cl. C23C 14/35; C23C 14/34

(52) U.S. Cl. CPC C23C 14/352; C23C 14/3407; C23C 14/3485
USPC 204/298.08; 204/298.12; 204/298.09; 204/298.13

(57) ABSTRACT

A sputtering apparatus including: a first target and a second target disposed to face each other; a magnetic field generating unit that is disposed on each rear surface of the first and second targets to generate a magnetic field; and a structure that is disposed between the first target and the second target and is formed of a doping material.

### CLAIM PRIORITY

This application makes reference to, incorporates the same herein, and claims all benefits accruing under 35 U.S.C. §119 from an application earlier filed in the Korean Intellectual Property Office on 13 Dec. 2012 and there duly assigned Serial No 10-2012-0145708.

### BACKGROUND OF THE INVENTION

1. Field of the Invention

The present invention generally relates to a sputtering apparatus.

2. Description of the Related Art

As a method for forming inorganic layers such as a metal layer or a transparent conductive layer, a sputtering method is often used.

The above information disclosed in this Related Art section is only for enhancement of understanding of the background of the invention and therefore it may contain information that does not form the prior art that is already known to a person of ordinary skill in the art.

### SUMMARY OF THE INVENTION

The present invention provides a sputtering apparatus whereby a target material and a doping material may be simultaneously formed on a substrate as layers.

According to an aspect of the present invention, there may be provided a sputtering apparatus including: a first target and a second target disposed to face each other; a magnetic field generating unit that may be disposed on each rear surface of the first and second targets to generate a magnetic field; and a structure that may be disposed between the first target and the second target and may be formed of a doping material.

The structure may include at least one doping material.

The structure may be disposed in a plasma discharge area formed between the first target and the second target.

The structure may be disposed at the same distances from both the first target and the second target.

The structure may have a circular cross-section.

The structure may be a mesh form.

The structure may include a plurality of horizontal axes and a plurality of vertical axes.

The plurality of horizontal axes and the plurality of vertical axes may be formed of a first doping material.

The plurality of horizontal axes and the plurality of vertical axes may be each alternately formed of a first doping material and a second doping material.

The plurality of horizontal axes and the plurality of vertical axes may be each alternately formed of a first doping material, a second doping material, and a third doping material.

The first target and the second target may be metal oxides, and the structure may include at least one doping material selected from the group consisting of SnF₂, WO₃, Nb₂O₅, and TiO₂Sn.

The structure may include a thermal coil and a doping material surrounding the thermal coil.

The magnetic field generating unit may include: an external magnet portion that may be disposed at an edge of the rear surfaces of the first target and the second target; and a central magnet portion that may be disposed on a center of the rear surfaces of the first target and the second target.

A power selected from the group consisting of a direct current power, a radio frequency (RF) power, and a DC pulse power may be applied to the first target and the second target.

According to another aspect of the present invention, there is provided a sputtering apparatus including: a first target and a second target facing each other; and a structure in a mesh form including a doping material disposed between the first target and the second target.

The structure may include a plurality of horizontal axes and a plurality of vertical axes.

The plurality of horizontal axes and the plurality of vertical axes may be formed of different doping materials and are alternately formed.

The structure may have a circular cross-section.

The structure may be formed of a thermal coil and a doping material surrounding the thermal coil.

The first target and the second target may be metal oxides, and the structure may include at least one doping material selected from the group consisting of SnF₂, WO₃, Nb₂O₅, and TiO₂Sn.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a conceptual diagram schematically illustrating an arrangement of components of a sputtering apparatus according to an embodiment of the present invention;

FIG. 2 is a conceptual diagram schematically illustrating an operation of forming a layer on a substrate using a heterogeneous material that is different from a target by using a structure in a sputtering apparatus according to an embodiment of the present invention;

FIGS. 3A through 3C are conceptual structural diagrams schematically illustrating a structure according to an embodiment of the present invention;

FIG. 4 is a conceptual diagram schematically illustrating mesh intervals and diameters of a structure according to an embodiment of the present invention; and

FIG. 5 is a schematic cross-sectional view of a structure according to another embodiment of the present invention.

### DETAILED DESCRIPTION OF THE INVENTION

The example embodiments are described more fully hereinafter with reference to the accompanying drawings. The inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. Expressions such as “at least one of,” when preceding a list of elements, modify the entire list of elements and do not modify the individual elements of the list. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross sectional illustrations that are schematic illustrations of illustratively idealized example embodiments (and intermediate structures) of the inventive concept. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In a sputtering method, a rare gas such as an argon (Ar) gas is introduced into a vacuum container, and a direct current (DC) power or radio frequency (RF) power is supplied to a cathode including a sputtering target at a high voltage as 150 V or higher to form layers through a glow discharge.

The sputtering method is typically used in forming layers for various manufacturing processes of flat panel display devices such as a thin film transistor liquid crystal display (TFT LCD) or organic light emitting display devices or in manufacturing processes of various electronic devices, and is known as a dry type process technique which has a wide range of application.

If an inert gas such as Ar or the like that is used for a plasma source is ionized, a surface of a deposition material plate is pressurized, and the material is vaporized, and reflection may occur. In addition, when an oxide based material is sputtered, for example, negative ions of oxygen reach a deposition substrate with a large energy due to an intense repulsive force in a cathode. In addition, according to the sputtering method, as particles have a high energy state of several eV or higher, when particles having a large motion energy reach the deposition substrate, a surface of the substrate may be damaged or thin films formed on the surface of the substrate may be sputtered.

In particular, when an inorganic layer is sputtered on an organic layer in order to form an upper electrode of an organic light emitting display device or an electrode of an organic thin film transistor, particles having a high energy of 100 eV or higher which are generated during a sputtering operation collide with the organic layer and may cause damages to the organic layer accordingly.

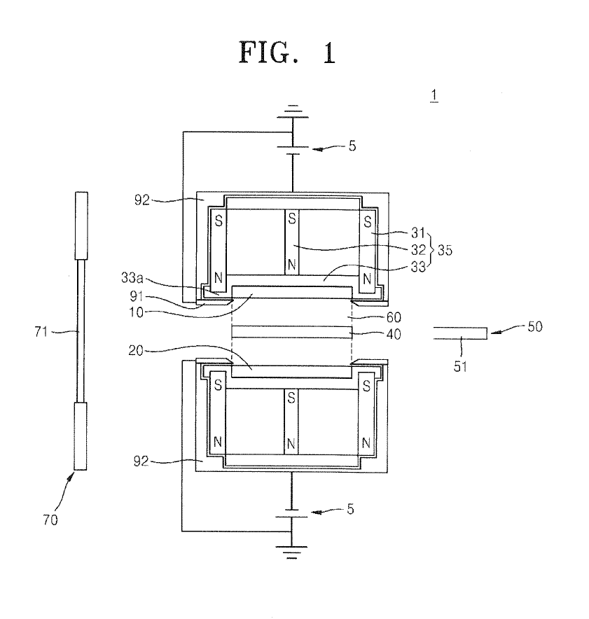

FIG. 1 is a conceptual diagram schematically illustrating an arrangement of components of a sputtering apparatus 1 according to an embodiment of the present invention.

Referring to FIG. 1, the sputtering apparatus 1 includes a structure 40 that may be disposed between a first target 10 and a second target 20 facing each other and may be used in doping a heterogeneous material on a substrate 71.

In detail, the sputtering apparatus 1 includes a first target 10 and a second target 20 that are disposed to face each other, a magnetic field generating unit 35 that may be disposed at each rear end of the first target 10 and the second target 20 to generate a magnetic field, a structure 40 that may be disposed between the first target 10 and the second target 20 to dope a heterogeneous material on a substrate 71, a gas supply pipe 50, and a substrate supporting portion 70.

While not shown in FIG. 1, the sputtering apparatus 1 may be disposed in a chamber that may be blocked from the external air. The chamber may be connected to a vacuum pump (not shown) by surrounding the exterior of components of the sputtering apparatus 1 and the substrate supporting portion 70 so as maintained a vacuum state.

The first target 10 and the second target 20 include a material that is to be deposited on the substrate 71. Also, the structure 40 includes at least one material that is to be doped on the substrate 71. For example, in regard to a manufacture of an organic light emitting display device, the first target 10 and the second target 20 may include various metals such as aluminum (Al), molybdenum (Mo), copper (Cu), gold (Au), or platinum (Pt) or alloys of these which are used to form a source electrode, a drain electrode or a gate electrode of a thin film transistor of the organic light emitting display device. In addition, the first target 10 and the second target 20 may include indium tin oxide (ITO), indium zinc oxide (IZO), indium oxide (IO), ZnO, tin zinc oxide (TZO), Al-doped ZnO (AZO), Ga-doped ZnO (GZO), or the like which are materials for forming layers of an anode electrode or a common electrode of an organic emissive layer.

In addition, the structure 40 may include at least one material such as SnF₂, WO₃, Nb₂O₅, or TiO₂ which is required in a small amount, as a material for providing functionality of the first and second targets 10 and 20. However, the embodiment of the present invention is not limited thereto, and any material which may be formed as a layer by using plasma formed between the first target 10 and the second target 20 may be used.

The gas supply pipe 50 may be disposed on a side of the first target 10 and the second target 20 to discharge a gas toward the first and second targets 10 and 20 through a supply nozzle 51. The gas supplied through the gas supply pipe 50 may be Kr, Ze, Ar, or a mixture gas of Ar and O₂.

A shield portion 91 may be disposed in front of each edge of the first and second targets 20. The shield portion 91 may be grounded so as to function as an anode. Also, the first and second targets 10 and 20 may each receive a negative (−) voltage from a power unit 5 to function as a cathode. The shield portion 91 may include the same material as a sputtering material, and may prevent pollution accordingly.

While direct current (DC) power may be used in the power unit 5, the embodiments of the present invention are not limited thereto, and radio frequency (RF) power or DC pulse power may also be used.

The sputtering apparatus 1 includes the magnetic field generating unit 35 that may be disposed at each rear end of the first and second targets 10 and 20 and generates a magnetic field. The magnetic field generating unit 35 may include an outer magnet portion 31 that may be disposed at an edge of each rear surface of the first and second targets 10 and 20.

The outer magnet portion 31 having a ring shape surrounding the edges of the rear surfaces of the first target 10 and the second target 20 (hereinafter referred to as the targets 10 and 20) may be manufactured.

The magnetic field generating unit 35 may further include a central magnet portion 32 that may be disposed at a center portion of each rear surface of the first target 10 and the second target 20. For example, the central magnet portion 32 having a bar shape may be manufactured. The outer magnet portion 31 may be manufactured to have stronger magnetic force than the central magnet portion 32.

Magnetic poles of the outer magnet portion 31 and the central magnet portion 32 are set to be in a direction approximately perpendicular to surfaces of the first target 10 and the second target 20. Also, the magnetic field generating unit 35 formed on the rear surface of the first target 10 and the magnetic field generating unit 35 formed on the rear surface of the second target 20 may be in opposite directions so as to form a magnetic field that connects the first target 10 and the second target 20.

As illustrated in FIG. 1, the outer magnet portion 31 and the central magnet portion 32 on the rear surface of the first target 10 have an N-pole in a downward direction, and the outer magnet portion 31 and the central magnet portion 32 on the rear surface of the second target 20 have an S-pole in an upward direction.

The magnetic field generating unit 35 may further include a yoke plate 33. The yoke plate 33 has a planar shape, and may be disposed between each of the first target 10 and the second target 20 and the outer magnet portion 31. The yoke plate 33 may preferably be formed of a material which may have magnetic properties by the outer magnet portion 31 and the central magnet portion 32. That is, the yoke plate 33 may be formed of a ferromagnetic substance by including one of iron, cobalt, nickel, and an alloy of these.

The yoke plate 33 may perform the function of making a magnetic field uniform by deflecting a direction of a magnetic field formed by the outer magnet portion 31 and the central magnet portion 32 in a direction perpendicular to surfaces of the first and second targets 10 and 20.

The yoke plate 33 may have a groove 33a surrounding an end portion of the outer magnet portion 31 facing the rear surfaces of the first and second targets 10 and 20. As such, as the yoke plate 33 surrounds end portions of the first and second targets 10 and 20, a strong magnetic field may be formed at the edges of the first and second targets 10 and 20, and thus, a plasma area may be limited to space between the first and second targets 10 and 20.

The outer magnet portion 31 and the central magnet portion 32 may be formed of a ferromagnetic body such as a ferrite based magnet, a neodymium based magnetic (e.g., neodymium, iron, or boron), or a samarium cobalt based magnet.

The first and second targets 10 and 20, the magnetic field generating unit 35, and the shield portion 91 may be surrounded by a case 92 having an opening portion. The first and second targets 10 and 20 may be disposed to be exposed through the opening portion of the case 92, and the shield portion 91 may be formed at the front sides of the first and second targets 10 and 20 on a front surface of the case 92.

The substrate supporting portion 70 may be disposed outside the sputtering apparatus 1 in a direction toward outer edges of the first target 10 and the second target 20. The substrate supporting portion 70 supports the substrate 71.

When the targets 10 and 20 which included as cathodes are discharged by applying a negative power of the power unit 5 thereto, electrons generated by discharging collide with argon (Ar) gas to generate Ar+ions, thereby generating plasma. Plasma may be confined in the space between the first target 10 and the second target 20 by a magnetic field generated by using the magnetic field generating unit 35. The plasma may include gamma-electrons, negative ions, positive ions, or the like.

Electrons in the plasma generated in the sputtering apparatus 1 form high-density plasma while rotating along a line of a magnetic force between the first and second targets 10 and 20 facing each other, and at the same time, the high-density plasma may be maintained as the first and second targets 10 and 20 reciprocally move by the negative power applied to the first and second targets 10 and 20.

All electrons or ions formed in the plasma or formed by an applied power rotate along a line of a magnetic force, and likewise, charged ion particles such as gamma-electrons, negative ions, positive ions or the like also reciprocally move along the line of magnetic force, and thus, charged particles having a high energy of 100 eV or higher are accelerated to the opposite target to be confined in the plasma formed in the space between the first and second targets 10 and 20.

Here, particles having a high energy from among particles sputtered in one of the first and second targets 10 and 20 are accelerated to the opposite target and thus hardly affect the substrate 71, and a thin film may be formed by diffusion of neutral particles having a relatively low energy.

A plasma discharge area 60 may be formed between the first target 10 and the second target 20, and the structure 40 may be disposed in the plasma discharge area 60.

The structure 40 has to be sputtered by energy of the plasma discharge area 60, and thus may have the same or smaller area than the plasma discharge area 60.

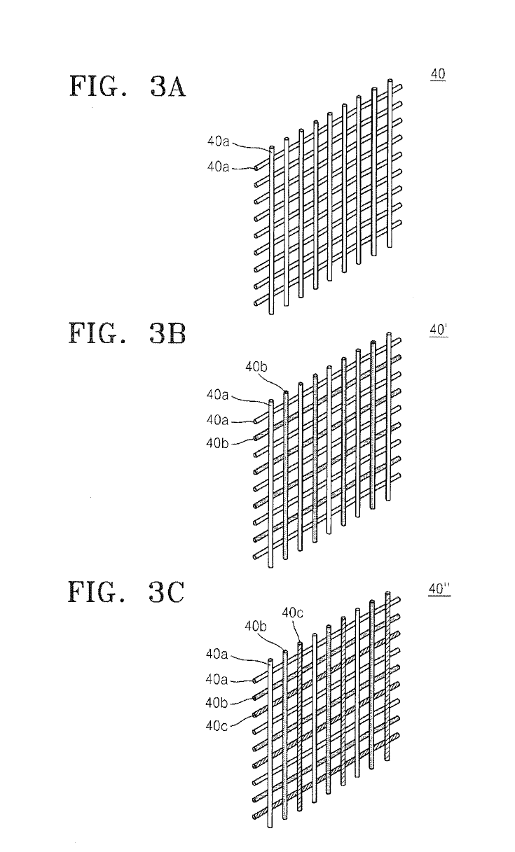

Also, in order to efficiently receive the energy of the plasma discharge area 60, the structure 40 may have an opening portion. For example, the structure 40 may be in a mesh form. However, the structure 40 is not limited thereto. A configuration of the structure 40 will be described in detail later with reference to FIGS. 3A through 3C.

Also, the substrate 70 may be doped with a plurality of heterogeneous materials by using the structure 40. The structure 40 may be formed of at least one doping material which is to be doped on the substrate 71.

Provided that the first target 10 and the second target 20 have the same components and energies emitted from the first and second targets 10 and 20 are equal, the structure 40 may be arranged at the same intervals from the first target 10 and the second target 20. However, the embodiment of the present invention is not limited thereto, and a location of the structure 40 may be varied according to the components of the first and second targets 10 and 20 and a difference in the energies emitted from the first and second targets 10 and 20. For example, if the first and second targets 10 and 20 have the same components but the energy emitted from the first target 10 may be larger than the energy emitted from the second target 20, the structure 40 may be disposed to be closer to the second target 20 than to the first target 10.

In addition, as the structure 40 may be disposed in the plasma discharge area 60, materials for forming the first and second targets 10 and 20 and a material for forming the structure 40 may be simultaneously formed on the substrate 71.

In addition, without having to add an additive or a doping material for improving and enhancing the properties to the first and second targets 10 and 20 in addition to the materials for forming the first and second targets 10 and 20 on the substrate 71, heterogeneous materials may be formed on the substrate 71 by using the structure 40, and thus, the manufacturing process may be simplified, thereby reducing the manufacturing costs and time.

Also, if a material added to the first and second targets 10 and 20 as an additive has characteristics of increasing resistance of the first and second targets 10 and 20, reduction in deposition speed of the sputtering apparatus 1 is inevitable. However, according to the current embodiment of the present invention, the structure 40 may be formed by using an additive, and the structure 40 may be separately used from the first and second targets 10 and 20. Thus, reduction in deposition speed of the sputtering apparatus 1 may be prevented, and the structure 40 may be easily formed using a desired additive material. Moreover, by replacing the structure 40 of the sputtering apparatus 1, a desired additive or doping material may be easily changed.

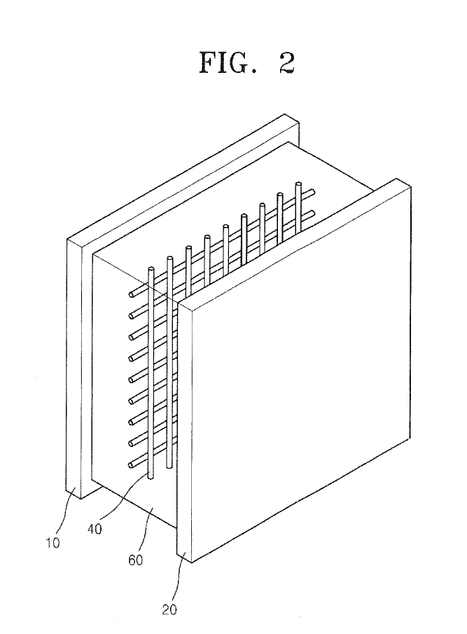

FIG. 2 is a conceptual diagram schematically illustrating an operation of forming a layer on a substrate using a heterogeneous material that is different from a target by using a structure in a sputtering apparatus according to an embodiment of the present invention. Like reference numerals as in FIG. 1 denote like elements, and description thereof will be omitted.

Referring to FIG. 2, the structure 40 may be disposed in the plasma discharge area 60 formed between the first target 10 and the second target 20.

To form main materials for forming layers on a substrate, the plasma discharge area 60 may be formed in front of the first and second targets 10 and 20. At the same time, a material of the structure 40 may be deposited on the substrate 71 from the structure 40 disposed in the plasma discharge area 60 by energy generated in the first and second targets 10 and 20 (heat and plasma).

FIGS. 3A through 3C are conceptual structural diagrams schematically illustrating the structure 40 according to an embodiment of the present invention.

FIG. 3A illustrates a structure of the structure 40 when one type of doping material may be formed on a substrate by using the structure 40.

The structure 40 may be a mesh form formed of a first doping material 40a included as a horizontal axis and a vertical axis. However, the current embodiment of the present invention is not limited thereto. Also, as the structure 40 may be formed of only the first doping material 40a, the first doping material 40a may be formed on a substrate in the plasma discharge area 60 together with a target material.

FIG. 3B illustrates a structure of a structure 40′ when two types of doping materials are formed on a substrate by using the structure 40′.

The structure 40′ may be a mesh form in which a first doping material 40a and a second doping material 40b are alternately formed along as a horizontal axis and a vertical axis. However, the current embodiment of the present invention is not limited thereto. Also, by using the structure 40′, the first doping material 40a and the second doping material 40b may be formed on a substrate in the plasma discharge area 60 together with a target material.

FIG. 3C illustrates a structure of a structure 40″ when three types of doping materials are formed on a substrate by using the structure 40″.

The structure 40″ may be a mesh form in which a first doping material 40a, a second doping material 40b, and a third doping material 40c are alternately formed along a horizontal axis and a vertical axis. However, the current embodiment of the present invention is not limited thereto. Also, by using the structure 40″, the first doping material 40a, the second doping material 40b, and the third doping material 40c may be formed on a substrate in the plasma discharge area 60 together with a target material.

While the structures 40′ and 40″ in which at least two doping materials are alternately formed are described above, the embodiments of the present invention are not limited thereto, and the arrangement of the plurality of doping materials may be varied according to process conditions.

In addition, while the structure 40″ formed of three, the first through third doping materials 40a, 40b, and 40c, the embodiments of the present invention are not limited thereto, and a structure may also include at least four different doping materials.

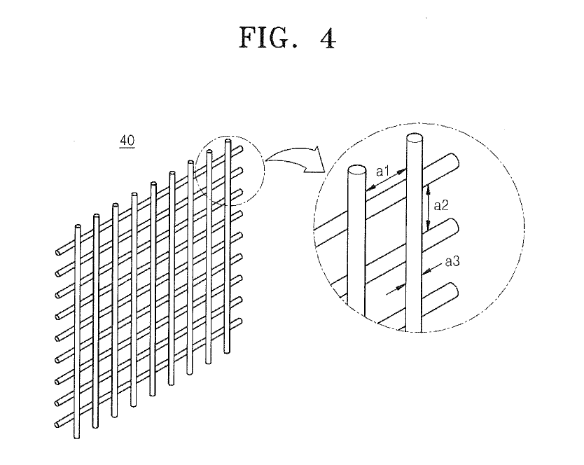

FIG. 4 is a conceptual diagram schematically illustrating mesh intervals and diameters of a structure 40 according to an embodiment of the present invention.

Referring to FIG. 4, the structure 40 includes a plurality of meshes, which have a first length a1, a second length a2, and a diameter a3.

The structure 40 having a mesh form may be disposed in the plasma discharge area 60 (see FIG. 1), and an inert gas such as Ar that may be injected during sputtering may collide in a proportion to a surface area of the meshes. That is, a speed that layers are formed on a substrate by using the structure 40 or a doping ratio of doping materials are proportional to the surface area of the structure 40.

Accordingly, by adjusting the first length a1, the second length a2, and the diameter a3 of the structure 40, a speed that a doping material of the structure 40 may be formed on a substrate and a doping ratio of doping materials may be adjusted.

In addition, the structure 40 having a mesh form may have a circular cross-section in order to have the highest spatial efficiency per unit surface, that is, surface area. However, the embodiments of the present invention are not limited thereto.

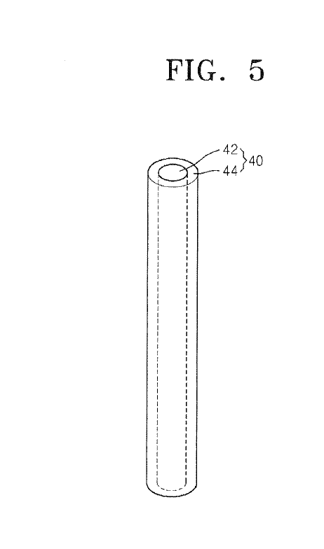

FIG. 5 is a schematic cross-sectional view of a structure 40 according to another embodiment of the present invention.

Referring to FIG. 5, the structure 40 includes a thermal line 42 and a doping material 44 surrounding the thermal line 42.

The structure 40 may be disposed in a plasma discharge area 60 (see FIG. 1) and used in depositing a doping material on a substrate together with a target material. However, if a temperature generated on a front surface of the target decreases the farther a distance between a target and the structure 40 is, doping efficiency of the structure 40 may be increased by supplying power to the thermal line 42.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A sputtering apparatus, comprising:
a first target and a second target disposed to face each other;
a magnetic field generating unit that is disposed on each rear surface of the first and second targets to generate a magnetic field; and
a structure that is disposed between the first target and the second target and is formed of a doping material.

2. The sputtering apparatus of claim 1, wherein the structure comprises at least one doping material.

3. The sputtering apparatus of claim 1, wherein the structure is disposed in a plasma discharge area formed between the first target and the second target.

4. The sputtering apparatus of claim 1, wherein the structure is disposed at the same distances from both the first target and the second target.

5. The sputtering apparatus of claim 1, wherein the structure has a circular cross-section.

6. The sputtering apparatus of claim 1, wherein the structure is a mesh form.

7. The sputtering apparatus of claim 6, wherein the structure comprises a plurality of horizontal axes and a plurality of vertical axes.

8. The sputtering apparatus of claim 6, wherein the plurality of horizontal axes and the plurality of vertical axes are formed of a first doping material.

9. The sputtering apparatus of claim 6, wherein the plurality of horizontal axes and the plurality of vertical axes are each alternately formed of a first doping material and a second doping material.

10. The sputtering apparatus of claim 6, wherein the plurality of horizontal axes and the plurality of vertical axes are each alternately formed of a first doping material, a second doping material, and a third doping material.

11. The sputtering apparatus of claim 1, wherein the first target and the second target are metal oxides, and the structure comprises at least one doping material selected from the group consisting of SnF₂, WO₃, Nb₂O₅, and TiO₂Sn.

12. The sputtering apparatus of claim 1, wherein the structure comprises a thermal coil and a doping material surrounding the thermal coil.

13. The sputtering apparatus of claim 1, wherein the magnetic field generating unit comprises:
an external magnet portion that is disposed at an edge of the rear surfaces of the first target and the second target; and
a central magnet portion that is disposed on a center of the rear surfaces of the first target and the second target.

14. The sputtering apparatus of claim 1, wherein a power source selected from the group consisting of a direct current power, a radio frequency (RF) power, and a DC pulse power is applied to the first target and the second target.

15. A sputtering apparatus, comprising:
a first target and a second target facing each other; and
a structure in a mesh form comprising a doping material disposed between the first target and the second target.

16. The sputtering apparatus of claim 15, wherein the structure comprises a plurality of horizontal axes and a plurality of vertical axes.

17. The sputtering apparatus of claim 15, wherein the plurality of horizontal axes and the plurality of vertical axes are formed of different doping materials and are alternately formed.

18. The sputtering apparatus of claim 15, wherein the structure has a circular cross-section.

19. The sputtering apparatus of claim 15, wherein the structure is formed of a thermal coil and a doping material surrounding the thermal coil.

20. The sputtering apparatus of claim 15, wherein the first target and the second target are metal oxides, and
the structure comprises at least one doping material selected from the group consisting of SnF₂, WO₃, Nb₂O₅, and TiO₂Sn.
